(19) United States
(12) Patent Application Publication
(10) Pub. No.: US 2008/0173950 A1
(43) Pub. Date: Jul. 24, 2008

(54) Structure and Method of Fabricating Electrical Structure Having Improved Charge Mobility

(75) Inventors: Huilong Zhu, Poughkeepsie, NY (US); Jing Wang, Beacon, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/624,375

(22) Filed: Jan. 18, 2007

(51) Int. Cl. H01L 27/092; H01L 21/8238

(52) U.S. Cl. 257/372; 438/218; 257/E21.632; 257/E27.063

(57) ABSTRACT

A method of fabricating an electrical structure with increased charge carrier mobility is provided. The method includes forming an N-type field effect transistor (nFET) device and a P-type field effect transistors (pFET) device on a semiconductor substrate; forming a compressive stress film over said nFET device for exerting tensile stress in a first channel associated with said nFET device; and forming a tensile stress film over said pFET device for exerting compressive stress in a second channel associated with said pFET. The method further includes forming at least one shallow region between a first gate associated with said nFET and a second gate associated with said pFET for generating conductive stresses in said first and second channels.

### BACKGROUND OF THE INVENTION

1. Technical Field

The present disclosure relates generally to field effect transistors and complementary metal-oxide semiconductor devices. In particular, the present disclosure relates to a structure and method of fabricating field effect transistors having improved charge carrier mobility for increased drive current capability.

2. Description of Related Art

Field effect transistors (hereinafter “FET) such as complementary metal-oxide semiconductor (hereinafter “CMOS”) are widely used in the electronic industry. FETs are employed in almost every electronic circuit application, such as, for example, signal processing, computing and wireless communications. There is constantly a demand for improved FETs performance, such as, for example, switching speed, on-state current capability, and on-state to off-state current ratio. These performance metrics tend to be improved by increasing the charge mobility of the FET. Hence researchers have been searching for new techniques to increase the charge carrier mobility of FETs.

It has been discovered that mechanical stress applied to the current channel of a FET can increase the charge carrier mobility. For example, Hamada et al. in “A New Aspect of Mechanical Stress Effects in Scaled MOS Devices” in IEEE Transactions on Electronic Devices, Vol. 38, No. 4, April 1991 describes the results of experiments in which performance characteristics of P-type FET (pFET) and N-type FET (nFET) transistors were measured as a function of mechanical stress. It was reported that longitudinal (i.e. in the direction of current flow) compression in pFET devices increased hole mobility, and longitudinal tension in nFET devices increased electron mobility. Usually, the stronger the stress the larger the mobility is.

However, incorporating strong mechanical stress into microfabricated FETs and CMOS devices has proven difficult. One major challenge is that the technique for producing stress in the devices must be compatible with the present device manufacturing practices and packaging techniques. A well known method of increasing the charge carrier mobility in FETs includes incorporating compressive stresses in pFETs and tensile stresses in nFET. For example, one common method to produce the desired stress in the channel area of FETs is by covering the FET with stressed films, such as, for example, nitride films. Hence, compressive nitride covers pFET and tensile nitride covers nFET. In order to reduce overlap capacitance in the gate portion of the FET, it is necessary to reduce the height of the gate portion. However, reduction of gate height cause the decreasing of the stress generated by the stressed films in the channel of the FETs. Thus the channel mobility of the FETS with short gates is degraded.

Accordingly, a need exist for an improved FET device having improved charge carrier mobility. It is an aspect of the present disclosure to provide a new and improved structure and method for fabricating field effect transistors having improved charge carrier mobility for increased drive current capability.

### SUMMARY OF THE INVENTION

The present disclosure is directed to a new and improved method of fabricating an electrical structure with improved charge mobility and having an N-type field effect transistor (nFET) device and a P-type field effect transistors (pFET) device formed on a semiconductor substrate. In one embodiment, a method is described, which includes forming a compressive stress film over the nFET device for exerting tensile stress in a first channel associated with the nFET device; and forming a tensile stress film over the pFET device for exerting compressive stress in a second channel associated with the pFET. The method further includes forming at least one shallow region between a first gate associated with the nFET and a second gate associated with the pFET; and etching a portion of a pad nitride layer formed over the at least one shallow region for generating conductive stresses in the first and second channels. Moreover, the method further includes shortening at least one of the first and second gate for reducing parasitic capacitance in the first and second gate.

In one embodiment, the forming of the tensile stress film includes etching a portion of the compressive stress film prior to forming the tensile stress film. In addition, the compressive dielectric layer is formed by depositing a polysilicon followed by oxidizing the polysilicon. Moreover, the forming of the compressive dielectric layer includes a blanket deposition of a silicon oxide buffer. The shallow region is formed by etching a portion of the tensile stress film.

In another embodiment, the method of increasing charge carrier mobility in an electrical structure having an N-type field effect transistor (nFET) device and a P-type field effect transistors (PFET) device formed on a semiconductor substrate includes forming a compressive stress film on a first gate associated with the nFET device to create longitudinal tensile stress in a channel of the nFET device; forming at least one shallow region adjacent the first gate and second gate; and forming a tensile stress film on a second gate associated with the pFET device to create longitudinal compressive stress in a channel of the pFET device. In this particular embodiment, the method further includes etching a portion of a pad nitride layer formed over the at least one shallow region for generating conductive stresses in the first and second channels; and shortening the first gate and second gate to reduce a parasitic capacitance in the first and second gate. In addition, the shortened first and second gates are dimensionally less than about 30 nm. Moreover, the at least one shallow region is positioned about 50 nm to about 400 nm from the first gate and second gates; and the at least one shallow region is shallow trench isolation structure. Further, the compressive stress film is selected from a group consisting of silicon nitride and silicon oxynitride; and the tensile stress film is selected from a group consisting of silicon nitride and silicon oxynitride.

In yet another embodiment, an electrical structure having a N-type field effect transistor (nFET) a P-type field effect transistors (pFET) formed on a semiconductor substrate, is described. The electrical structure includes a compressive stress film overlying a gate associated with the nFET, wherein the compressive stress film creates longitudinal tensile stress in a channel area of the nFET; and a tensile stress film overlying a gate associated with the pFET, wherein the tensile stress film creates compressive stress in a channel area of the pFET. The electrical structure further includes a shallow region positioned between the nFET and the pFET, where the shallow region is a shallow trench isolation structure. In one embodiment, the shallow region is positioned about 50 nm to about 400 nm from the first and second gates.

Other features of the presently disclosed structure and method for fabricating field effect transistors having improved charge carrier mobility for increased drive current capability will become apparent from the following detail description taken in conjunction with the accompanying drawing, which illustrate, by way of example, the presently disclosed structure and method.

### BRIEF DESCRIPTION OF THE DRAWINGS

The features of the presently disclosed structure and method of fabricating field effect transistors having improved charge carrier mobility for increased drive current capability will be described hereinbelow with references to the figures, wherein:

FIG. 1 illustrates a simplified cross-sectional view of a portion of a conventional electrical structure device having an nFET and a pFET formed on a semiconductor substrate, according to one embodiment of the present disclosure;

FIG. 2 illustrates the electrical structure of FIG. 1 following the shortening of the gates of the nFET and the pFET;

FIG. 3 illustrates the electrical structure of FIG. 2 following a compressive nitride film deposition, in accordance with the present disclosure;

FIG. 4 illustrates the electrical structure of FIG. 3 following a photoresist patterning;

FIG. 5 illustrates the electrical structure of FIG. 4 following the partial removal of the first dielectric stress layer;

FIG. 6 illustrates the electrical structure of FIG. 5 following a tensile nitride film deposition and a photoresist patterning;

FIG. 7 illustrates the electrical structure of FIG. 6 following an etching process for defining a shallow region;

FIG. 8 illustrates the electrical structure of FIG. 7 following the deposition of a pad nitride layer; and

FIG. 9 is an exemplary process flow diagram illustrating a method of increasing charge carrier mobility in an electrical structure having a pFET and a nFET formed on a semiconductor substrate, in accordance with the present disclosure.

### DETAILED DESCRIPTION

Referring now to the drawing figures, wherein like reference numerals identify identical or corresponding elements, an embodiment of the presently disclosed structure and method of increasing charge carrier mobility in an electrical structure will be described in detail. In the following description, the numerous specific details provided, such as, for example, particular structures, components, materials, dimensions, processing steps and techniques, are set forth for facilitating a thorough understanding of the present disclosure. However, it will be appreciated by one of ordinary skill in the art that the embodiments in the present disclosure may be practiced without the specific details provided herein. In other instances, well-known structures or processing steps have not been described in detail to avoid obscuring the invention.

It will be understood that when a layer is referred to as being “on” or “over” another layer, it can be directly on the other element or intervening layers may also be present. In contrast, when a layer is referred to as being “directly on” or “directly over” another layer, there are no intervening layers present. It will also be understood that when a layer is referred to as being “connected” or “coupled” to another layer, it can be directly connected to or coupled to the other layer or intervening layers may be present. In contrast, when a layer is referred to as being “directly connected” or “directly coupled” to another layer, there are no intervening layers present.

Although the present disclosure is described in reference to an exemplary nFET and pFET devices (e.g. CMOS), it will be appreciated that the method of the present disclosure may be applied to the formation of any electrical device.

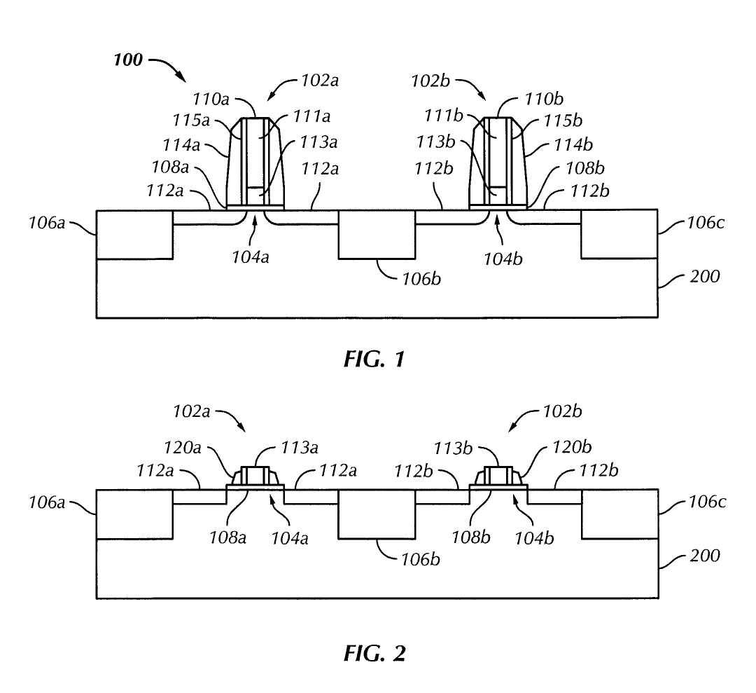

FIGS. 1-9 illustrate an exemplary method of fabricating an electrical structure having nFET and pFET devices formed on a semiconductor substrate. In particular, the present disclosure provides nFET and pFET devices having stressed channel regions for enhanced charge carrier mobility. More in particular, a metal gate nFET and pFET is formed over a semiconductor substrate both having a shortened gage for reducing parasitic capacitance. A dual stress liner process is followed for covering nFET with compressive nitride film and pFET with tensile nitride film. A portion of the nitride films is etched adjacent to the gates for generating stresses that enhance the FET performance.

With initial reference to FIG. 1, an embodiment of an electrical structure, in accordance with the present disclosure, is illustrated and is designated generally as electrical structure 100. Electrical structure 100 includes an nFET device 102A and a pFET device 102B formed on a base semiconductor substrate 200. Base semiconductor substrate 200 may include any of several semiconductor materials including, but not limited to silicon, germanium, silicon-germanium, silicon-germanium alloys, silicon carbide, silicon-germanium carbide alloy, other III-V or II-VI compound semiconductors, or organic semiconductor structures. Typically, semiconductor substrate 200 may be about, but is not limited to, several hundred microns thick, such as, for example a thickness ranging from about 0.2 mm to about 3 mm.

With continued reference to FIG. 1, a current channel 104A and a current channel 104B are disposed on semiconductor substrate 200 and are associated with nFET and pFET devices, respectively. Isolation areas, such as, for example, shallow trench isolation (STI) structures 106A, 106B and 106C are formed for electrically isolating consecutive FET devices. In this particular embodiment, for example, STI structure 106b isolates nFET device 102A from pFET device 102B. Source/drain extension 112A and 112B connect to channels 104A and 104B, respectively. In addition, gate dielectrics 108A and 108B are disposed over channels 104A and 104B, respectively. Gate conductors 110A and 110B corresponding to nFET and pFET devices 102A, 102B, respectively, are also provided. It is noted that gate conductors 110A and 110B includes a top portion of poly-SiGe 111A, 111B and a bottom portion of Poly-Si 113A, 113B. In one embodiment, gate conductors 110A and 110B include a layer of polysilicon-germanium layer (not shown) formed for facilitating shortening of gate conductors 108A and 108B, as described hereinbelow. Sidewall spacers 114A and 114B are formed adjacent to stacked gate electrodes 110A and 110B. Offset spacers 115A and 115B are formed between sidewall spacers 114A and 114B and gate conductors 110A and 110B, respectively. Offset spacers 115A and 115B are typically used for controlling halo and extension implantation.

With reference to FIG. 2, nFET and pFET devices 102A and 102B are significantly reduced in height following a process well known in the art, by shortening gate conductors 110A, 110B, gate dielectrics 113A, 113B and spacers 120A, 120B, as illustrated by the figure. The resulting structure includes shortened gate conductors 113A, 113B and shortened spacers 120A, 120B. In particular, a dimensional height of gate electrode 110A and 110B is substantially reduced, such that shortened gates 113A and 113B may be, for example, less than about 40 nm. The shortening of gate electrodes 113A and 113B results in the reduction of parasitic capacitance in channels 104A and 104B. Due to reduction of gate sidewall area, the parasitic capacitance between gate and metal vias adjacent to the gate is reduced.

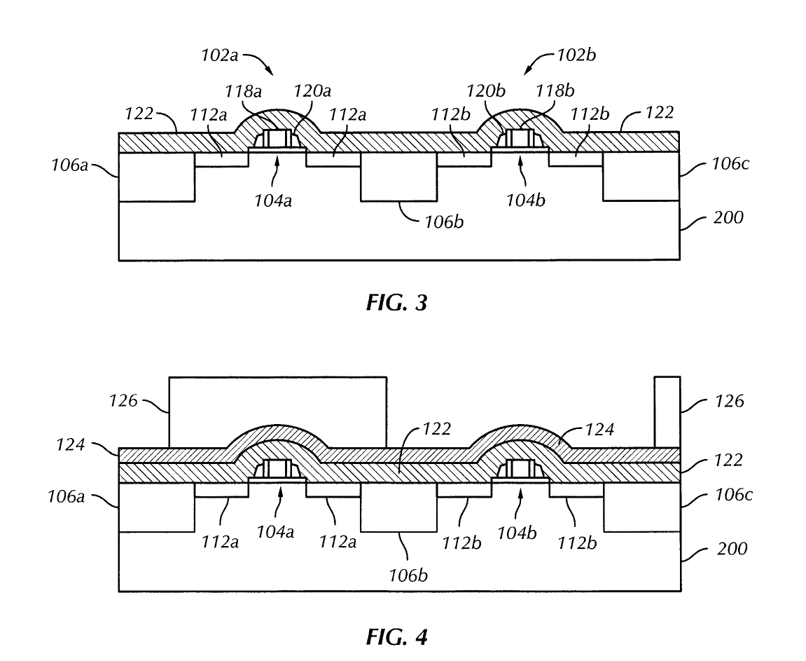

With reference to FIG. 3, a blanket deposition of a compressive nitride film 122 is formed over structure 100 to generate compressive stress in both channel 104A and 104B of nFET device 102A and pFET device 102B. In one embodiment, compressive nitride film 122 ranges in thickness from about 40 nm to about 100 nm. In addition, compressive nitride film 122 is deposited by a chemical vapor deposition (hereinafter “CVD”) process where the relative reactant flow rates, deposition pressure, and temperature may be varied to vary a composition of the dielectric layer thereby controlling the level of either compressive or tensile stress.

With reference to FIG. 4, using conventional methods known in the art, a blanket deposition of a silicon oxide buffer layer 124 over compressive nitride film 122 is formed for facilitating the subsequent etching of compressive nitride film 122. A photoresist pattern 126 is then formed over the compressive nitride film 122 covering nFET device 102A and an area adjacent to pFET device 102B. In one embodiment, silicon oxide buffer layer 124 includes a thickness of about 10 nm to about 50 nm and photoresist pattern 126 may include a thickness of about 100 nm to about 300 nm.

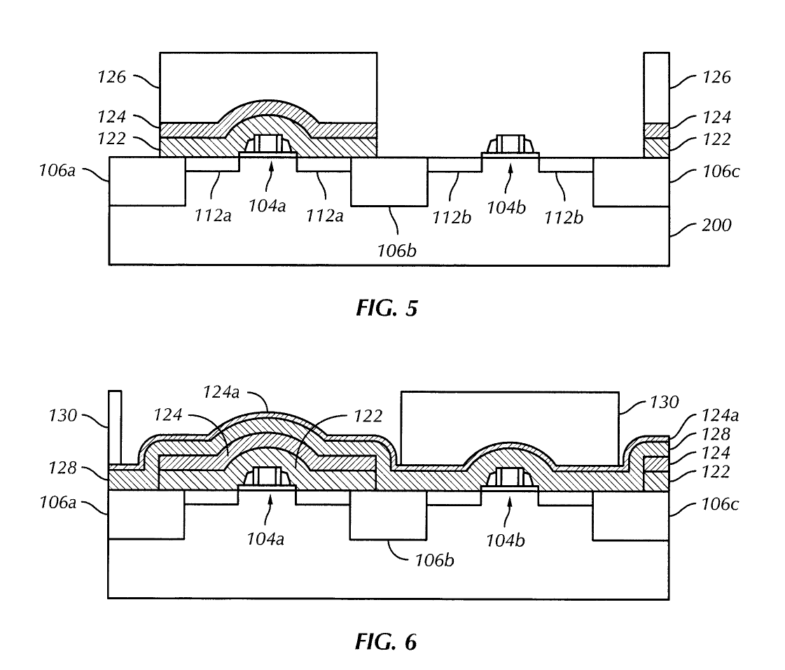

With reference to FIG. 5, oxide buffer layer 124 and compressive nitride film 122 are removed from pFET device 102B using a reactive ion etch (hereinafter “RIE”). By etching compressive nitride film 122 and oxide buffer layer 124, tensile stress is exerted in channel 104A of nFET device 102A, thus enhancing the performance of nFET device 102A. Photoresist pattern 126 is then removed.

With reference to FIG. 6, a blanket deposition of a tensile nitride film 128 is formed over structure 100 for generating tensile stress in both channel 104A and 104B of nFET device 102 A and pFET device 102B. Tensile nitride film 128 ranges in thickness from about 50 nm to about 100 nm. A blanket deposition of a thin silicon oxide buffer layer 124a, ranging in thickness from about 5 nm to about 30 nm, is formed over tensile nitride film 128. Next, a photoresist pattern 130 is formed over pFET device 102B and an area adjacent to nFET device 102A, as illustrated by the figure.

In one particular embodiment, compressive and tensile nitride film 122 and 128 may include, for example, a silicon nitride (e.g., SiN, SiₓN_{y}) or silicon oxynitride (e.g., SiₓON_{y}), where the soichiometric proportions x and y may be selected according to CVD process variables, as known in the art, for achieving a desired compressive or tensile stress in a deposited dielectric layer. For example, the CVD process may be a low pressure chemical vapor deposition (LPCVD) process, an atomic layer CVD (ALCVD) process, or a plasma enhanced CVD (PECVD) process. The SiₓN_{y} may contain other elements such as hydrogen that can change stress in the SiₓN_{y}.

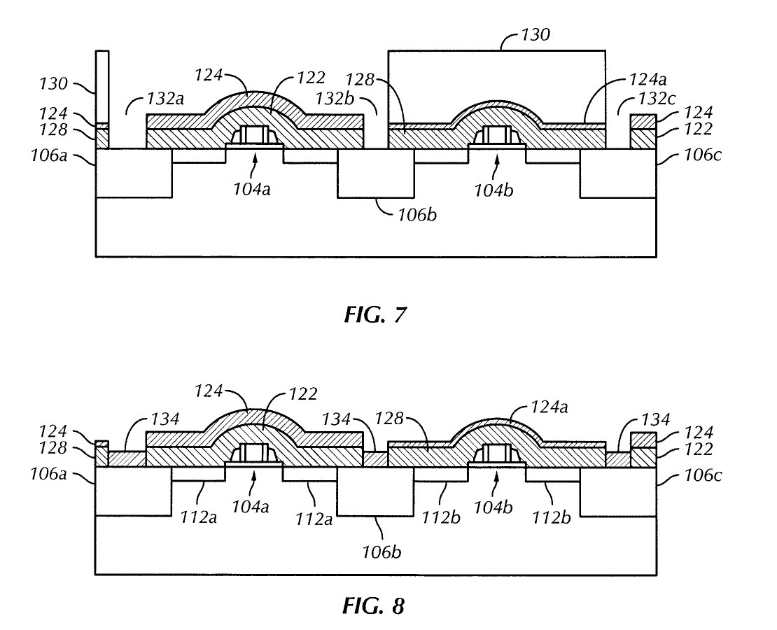

With reference to FIG. 7, a RIE process is followed to etch oxide buffer layer 124a and tensile nitride film 128 on nFET device 102A and for forming shallow areas 132a, 132b and 132c. In addition, following the RIE process, the stress in channel 104B of pFET device 102A becomes compressive, thus enhancing the performance of pFET device 102A. In one embodiment, shallow regions 132a, 132b and 132c may include shallow trench isolation (STI) oxide material. In addition, shallow regions 132a, 132b and 132c may be positioned about 50 nm to about 400 nm from gate conductors 110A and 110B. Photoresist pattern 126 is then removed.

With reference to FIG. 8, a pad nitride 134 ranging in thickness from about 0.5 nm to about 1.0 nm is formed over structure 100, including shallow regions 132a, 132b and 132c. Pad nitride layer 134 is then etched back leaving behind a portion in shallow regions 132a, 132b and 132c. Pad nitride layer is included for reducing moist and to protect the devices under the nitride films. Next, conventional process steps are then followed to complete fabrication of the nFET and pFET devices, as well know in the semiconductor art.

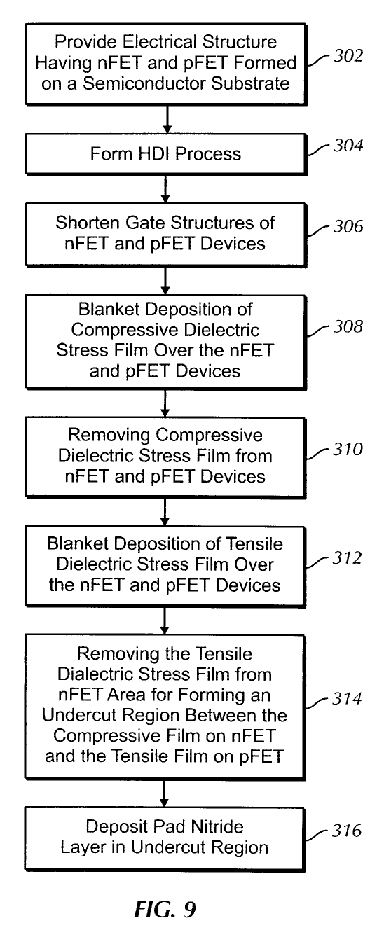

FIG. 9 presents a process flow diagram illustrating a method for enhancing charge mobility in an electrical structure having a pFET and an nFET formed on a semiconductor substrate, in accordance with one embodiment of the present disclosure. Initially, at step 302, an electrical structure 100 having an nFET device 102A and a pFET device 102B formed on a semiconductor device 200 is provided. At step 304, a high dose implant (HDI) doping process is performed to form a high dose implant portion of doped S/D regions 112A and 112B and followed by SD anneal to activate dopants in nFET device 102A and pFET device 102B. At step 306, nFET and pFET devices 102A, 102B are shortened. At step 308, a blanket deposition of a compressive nitride film 122 is formed over nFET and pFET devices 102A, 102B. At step 310, compressive nitride film 122 is then removed from the pFET area. At step 312, a blanket deposition of tensile nitride film 128 is formed over the nFET and pFET devices 102A, 102B. At step 314, tensile nitride film 128 is then removed from the nFET area for defining an undercut region 132. At step 316, a pad nitride layer is deposited in the undercut region 132. Finally, conventional processes are then carried out to complete formation of MOSFET devices.

It will be understood that numerous modifications and changes in form and detail may be made to the embodiments of the present disclosure. While FIGS. 1-9 illustratively demonstrate exemplary device structure and processing steps that can be used to form such exemplary device structure, according to specific embodiments of the present disclosure, it is clear that a person ordinarily skilled in the art can be modify the demonstrated device structures as well as the process steps for adaptation to specific application requirements, consistent with the above description. For example, the nitride film may be deposited in arbitrary order provided that the compressive nitride film is formed over the nFET device portion and the tensile nitride film is formed over the pMOS device portion. It should therefore be recognized that the present disclosure is not limited to the specific embodiment illustrated hereinabove, but rather extends in utility to any other modification, variation, application and embodiment, and accordingly all such other modifications, variations, applications and embodiments are to be regarded as being within the spirit and scope of the disclosure. In short, it is Applicant's intention that the scope of the patent issuing herefrom will be limited only by the scope of the appended claims. Having thus described the invention with the details and particularity required by the patent laws, what is claimed and desired protected is set forth in the appended claims.

What is claimed is:

1. A method of fabricating an electrical structure with improved charge mobility and having an N-type field effect transistor (nFET) device and a P-type field effect transistors (PFET) device formed on a semiconductor substrate, the method comprising:
forming a compressive stress film over said nFET device for exerting tensile stress in a first channel associated with said nFET device; and
forming a tensile stress film over said pFET device for exerting compressive stress in a second channel associated with said pFET.

2. The method of fabricating an electrical structure as recited in claim 1, further comprising:
forming at least one shallow region between a first gate associated with said nFET and a second gate associated with said pFET; and
etching a portion of a pad nitride layer formed over said at least one shallow region for generating conductive stresses in said first and second channels.

3. The method of fabricating an electrical structure as recited in claim 1, further comprising shortening at least one of said first and second gate for reducing parasitic capacitance in said first and second gate.

4. The method of fabricating an electrical structure as recited in claim 1, wherein said forming a tensile stress film includes etching a portion of said compressive stress film prior to forming said tensile stress film.

5. The method of fabricating an electrical structure as recited in claim 1, wherein said compressive dielectric layer is formed by depositing a polysilicon followed by oxidizing said polysilicon.

6. The method of fabricating an electrical structure as recited in claim 1, wherein said forming of said compressive dielectric layer includes a blanket deposition of a silicon oxide buffer.

7. The method of fabricating an electrical structure as recited in claim 1 wherein said shallow region is formed by etching a portion of said tensile stress film.

8. A method of increasing charge carrier mobility in an electrical structure having an N-type field effect transistor (nFET) device and a P-type field effect transistors (pFET) device formed on a semiconductor substrate, the method comprising:
forming a compressive stress film on a first gate associated with said nFET device to create longitudinal tensile stress in a channel of said nFET device;
forming at least one shallow region adjacent said first gate and second gate; and
forming a tensile stress film on a second gate associated with said pFET device to create longitudinal compressive stress in a channel of said pFET device.

9. The method of increasing charge carrier mobility as recited in claim 8, further comprising etching a portion of a pad nitride layer formed over said at least one shallow region for generating conductive stresses in said first and second channels.

10. The method of increasing charge carrier mobility as recited in claim 8, further comprising shortening said first gate and second gate to reduce a parasitic capacitance in said first and second gate.

11. The method of increasing charge carrier mobility as recited in claim 10, wherein said shortened first and second gates are dimensionally less than about 30 nm.

12. The method of increasing charge carrier mobility as recited in claim 8, wherein said at least one shallow region is positioned about 50 nm to about 400 nm from said first gate and second gates.

13. The method of increasing charge carrier mobility as recited in claim 8, wherein said at least one shallow region is shallow trench isolation structure.

14. The method of increasing charge carrier mobility as recited in claim 8, wherein said compressive stress film is selected from a group consisting of silicon nitride and silicon oxynitride.

15. The method of enhancing charge mobility as recited in claim 8, wherein said tensile stress film is selected from a group consisting of silicon nitride and silicon oxynitride.

16. The method of increasing charge carrier mobility as recited in claim 8, wherein said at least one shallow region is shallow trench isolation structure.

17. An electrical structure having a N-type field effect transistor (nFET) a P-type field effect transistors (pFET) formed on a semiconductor substrate, the electrical structure comprising:
a compressive stress film overlying a gate associated with said nFET, wherein said compressive stress film creates longitudinal tensile stress in a channel area of said nFET; and
a tensile stress film overlying a gate associated with said pFET, wherein said tensile stress film creates compressive stress in a channel area of said pFET.

18. The electrical structure as recited in claim 17, further comprising a shallow region positioned between said nFET and said pFET.

19. The electrical structure as recited in claim 18, wherein said shallow region is a shallow trench isolation structure.

20. The electrical structure as recited in claim 18, wherein said shallow region is positioned about 50 nm to about 400 nm from said first and second gates.
